(19) United States
(12) Patent Application Publication
(10) Pub. No.: US 2025/0299929 A1
(43) Pub. Date: Sep. 25, 2025

(54) SUBSTRATE SUPPORT ASSEMBLY HAVING AN EDGE VOLTAGE DELIVERY SYSTEM

(71) Applicant: Applied Materials, Inc., Santa Clara, CA (US)

(72) Inventors: Yogananda SARODE VISHWANATH, Bangalore (IN); Rajinder DHINDSA, Pleasanton, CA (US); Anand KUMAR, Bangalore (IN); Denis Martin KOOSAU, Sunnyvale, CA (US); John POULOSE, Sunnyvale, CA (US); James ROGERS, Los Gatos, CA (US)

(21) Appl. No.: 18/614,816

(22) Filed: Mar. 25, 2024

(51) Int. Cl. H01J 37/32; H01L 21/687

(52) U.S. Cl. CPC H01J 37/32477; H01J 37/321; H01J 37/32568; H01J 37/32642; H01L 21/68735

(57) ABSTRACT

The present disclosure relates to a protective ring for an edge electrode, an edge voltage delivery system, and a substrate support assembly. The protective ring for a substrate support assembly includes an annular body including a first top surface and a first bottom surface; a protrusion disposed along an inner perimeter of the annular body and including a second top surface and a second bottom surface, the second top surface being disposed below the first top surface; and a skirt disposed along an outer perimeter of the annular body and extending downwardly from the first bottom surface. The skirt, the protrusion, and the first bottom surface form a groove under the annular body. The groove is configured to receive the edge electrode. Both the edge voltage delivery system and the substrate support assembly include the protective ring and the edge electrode.

### BACKGROUND

### Field

Examples of the present disclosure generally relate to a substrate support assembly having an edge voltage delivery system, and more particularly, to a substrate support assembly including an edge electrode assembly capable of applying voltage in proximity to edges of a substrate.

### Description of the Related Art

A semiconductor substrate may undergo various processes, such as deposition, etch, and removal of materials, before becoming semiconductor devices. To lower cost and improve performance of a semiconductor device, semiconductor process has increasingly put more stringent requirements on dimension uniformity and process yields. However, edge effects, such as process non-uniformities, often exist at the perimeter or edge of a substrate. For example, the etch profile at edges of the substrate may deviate from that at the center of the substrate due to different ion density, sheath size, RF uniformity, or previous processing. These edge effects reduce usable die yield near the edge of the substrate.

Conventional processing controls have included several tunable knobs for controlling process uniformity across a substrate. A known technique is to utilize an edge electrode to tune the voltage applied to edges of a substrate. The edge electrode can improve the edge profile of a substrate, such as thickness and tilting. Conventional edge electrodes may include a conducive material embedded in a dielectric material and placed adjacent to a substrate for supplying voltages to control the edge profile. However, the embedded conductor in the edge electrode may not be close enough to the edges of a substrate due to the limitation inherent to the embedded design of the edge electrode.

Therefore, there is a need for a substrate support assembly with an improved edge voltage delivery system.

### SUMMARY

Disclosed herewith are a protective ring for an edge electrode, an edge voltage delivery system, and a substrate support assembly. The protective ring is configured to separate an edge electrode from a susceptor and a plasma environment. The edge electrode may be made of a metal, such as aluminum. In an embodiment, the protective ring for a substrate support assembly includes an annular body including a first top surface and a first bottom surface; a protrusion disposed along an inner perimeter of the annular body and including a second top surface and a second bottom surface, the second top surface being disposed below the first top surface; and a skirt disposed along an outer perimeter of the annular body and extending downwardly from the first bottom surface. The skirt, the protrusion, and the first bottom surface form a groove under the annular body. The groove is configured to receive the edge electrode.

In an embodiment, the edge voltage delivery system includes the protective ring as set forth in various embodiments of the present disclosure, an edge electrode made of a conductive material and disposed under the protective ring; and a plurality of electrical feed lines coupled with the edge electrode.

In an embodiment, the substrate support assembly for a processing chamber includes a susceptor configured to support a substrate; an edge ring surrounding the susceptor; and an edge voltage delivery system configured to deliver an electrical signal in proximity to an edge of the susceptor. The edge voltage delivery system includes the protective ring and the edge electrode as set forth in various embodiments of the present disclosure.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic cross-sectional view of a processing chamber, according to one embodiment of the disclosure.

FIG. 2 illustrates a schematic top view of a substrate support assembly, according to an embodiment.

FIG. 3 illustrates a schematic configuration of an edge voltage delivery system, according to an embodiment.

FIG. 4A illustrates a schematic cross-section view along lines A-A of FIG. 2, according to an embodiment.

FIG. 4B illustrates a schematic configuration of Callout B in FIG. 4A, according to an embodiment.

FIG. 5A illustrates a schematic top view of a protective ring for the edge voltage delivery system, according to an embodiment.

FIG. 5B illustrate a schematic cross-sectional view along lines C-C of FIG. 5A, according to an embodiment.

FIG. 6A illustrates a schematic top view of an edge electrode, according to an embodiment.

FIG. 6B illustrates a schematic cross-sectional view along lines D-D of FIG. 6A, according to an embodiment.

FIG. 7A illustrates a schematic top view of an edge ring, according to an embodiment.

FIG. 7B illustrates a schematic cross-sectional view along lines E-E of FIG. 7A, according to an embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to a substrate support assembly having an edge voltage delivery system capable of applying an edge voltage in proximity of edges of a susceptor. In an embodiment, the edge voltage delivery system includes an edge electrode made of a conductive material. The edge electrode surrounds a susceptor of the substrate support assembly and configured to apply edge voltages to edges of the substrate. A plurality of electric feed lines are coupled with the edge electrode to supply the edge voltage. A protective ring is disposed on top of the edge electrode. An edge ring is disposed around an outer perimeter of the edge electrode for protection.

The edge voltage delivery system of the present disclosure is capable of applying an edge voltage in proximity of the edges of a substrate, allowing a finer control of the edge profile. The protective ring and the edge electrodes of the edge voltage delivery system can be easily maintained or replaced, reducing the downtime of the equipment.

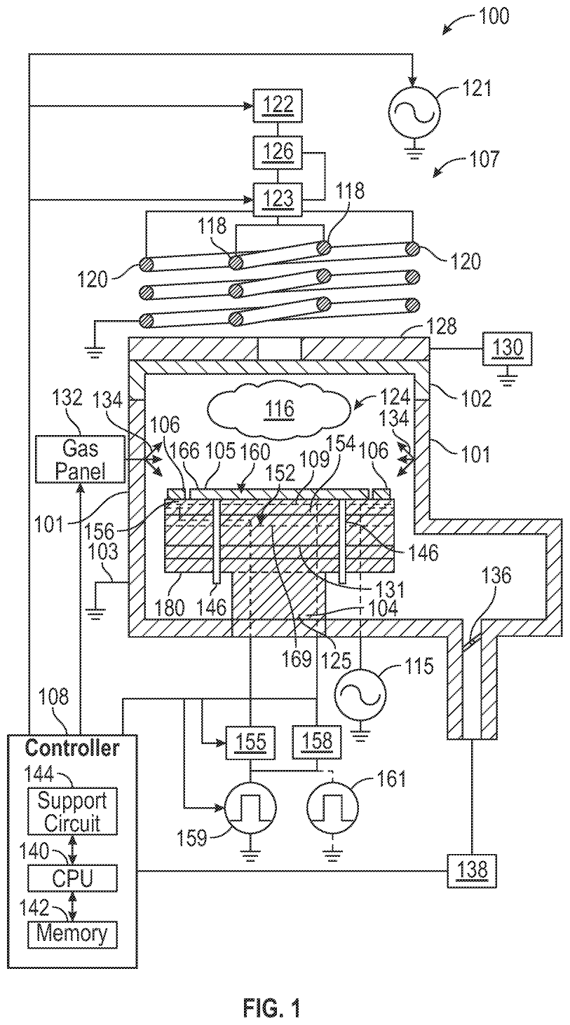

FIG. 1 illustrates a schematic cross-sectional view of a processing chamber 100, according to one example of the disclosure. The processing chamber 100 includes an edge voltage delivery system 106 disposed in a substrate support assembly 104, as set forth in various embodiments of the present disclosure.

The processing chamber 100 includes a chamber body 101 and a lid 102 disposed thereon that together define an internal volume 124. The chamber body 101 is typically coupled to an electrical ground 103. The substrate support assembly 104 is disposed within the internal volume 124 to support a substrate 105 thereon during processing. An edge voltage delivery system 106 is positioned on the substrate support assembly 104 and surrounds the periphery of the substrate 105. The processing chamber 100 also includes an inductively coupled plasma apparatus 107 for generating a plasma 116 of reactive species within the processing chamber 100, and a controller 108 adapted to control systems and subsystems of the processing chamber 100.

The substrate support assembly 104 is disposed in the internal volume 124. The substrate support assembly 104 generally includes at least a substrate support body 152. The substrate support body 152 includes a susceptor 154 configured to underlay and support the substrate 105 during processing. In an embodiment, an edge electrode 156 is included in the substrate support assembly and configured to supply an edge voltage to a location that is in proximity to edges of the substrate 105. The edge electrode 156 may be included in the edge voltage delivery system 106. An edge voltage control circuit 155 is coupled to the edge electrode 156.

A substrate electrode 109 may be embedded in the substrate support body 152 for applying a voltage to the substrate 105. A substrate voltage control circuit 158 is coupled to the electrode 109.

In an embodiment, two voltage sources 159 and 161 are provided to supply two shaped DC pulse voltages. For example, the first voltage source 159 is coupled to the edge voltage control circuit 155 for supplying a first shaped DC pulse voltage, while a second voltage source 161 is coupled to the substrate voltage control circuit 158 for supply a second shaped DC pulse voltage. The edge voltage control circuit 155 and the substrate voltage control circuit 158 are independently tunable to generate a difference in voltage between the edge voltage and the substrate voltage. The substrate voltage control circuit 158 and the edge voltage control circuit 155 each include variable and/or fixed capacitors and/or inductors to provide the independent tunability of the edge ring voltage and the substrate voltage.

In one embodiment, the first voltage source 159 is coupled to both the edge voltage control circuit 155 and the substrate voltage control circuit 158 for supplying a first shaped DC pulse voltage. The substrate electrode 109 is further coupled to a chucking power source 115 and is configured to chuck the substrate 105 to the upper surface 160 of the substrate support body 152 during processing.

The substrate support assembly 104 may additionally include a heater assembly 169. The substrate support assembly 104 may also include a cooling base 131. The cooling base 131 may alternately be separate from the substrate support assembly 104. The substrate support assembly 104 may be removably coupled to a support pedestal 125. The support pedestal 125 is mounted to the chamber body 101 and may include a pedestal base (not shown). The support pedestal 125 may optionally include a facility plate 180 configured to accommodate a plurality of fluid channels (not shown). The substrate support assembly 104 may be periodically removed from the support pedestal 125 to maintain one or more components of the substrate support assembly 104. Lifting pins 146 are disposed through the substrate support assembly 104 as conventionally known to facilitate substrate transfer.

The inductively coupled plasma apparatus 107 is disposed above the lid 102 and is configured to inductively couple RF power to gasses within the processing chamber 100 to generate a plasma 116. The inductively coupled plasma apparatus 107 includes first and second coils 118, 120, disposed above the lid 102. The relative position, ratio of diameters of each coil 118, 120, and/or the number of turns in each coil 118, 120 can each be adjusted as desired to control the profile or density of the plasma 116 being formed. Each of the first and second coils 118, 120 is coupled to an RF power supply 121 through a matching network 122 via an RF feed structure 123. The RF power supply 121 may illustratively be capable of producing up to about 4000 W (but not limited to about 4000 W) at a tunable frequency in a range from 50 kHz to 13.56 MHZ, although other frequencies and powers may be utilized as desired for particular applications.

In some examples, a power divider 126, such as a dividing capacitor, may be provided between the RF feed structure 123 and the RF power supply 121 to control the relative quantity of RF power provided to the respective first and second coils 118, 120. In some examples, the power divider 126 may be incorporated into the matching network 122. In other embodiments, capacitively coupled plasma apparatus can be used above the lid 102.

A heater element 128 may be disposed on the lid 102 to facilitate heating the interior of the processing chamber 100. The heater element 128 may be disposed between the lid 102 and the first and second coils 118, 120. In some examples, the heater element 128 may include a resistive heating element and may be coupled to a power supply 130, such as an AC power supply, configured to provide sufficient energy to control the temperature of the heater element 128 within a desired range.

During operation, the substrate 105, such as a semiconductor substrate or other substrate suitable for plasma processing, is placed on the substrate support assembly 104. Substrate lift pins 146 are movably disposed in the substrate support assembly 104 to assist in transfer of the substrate 105 onto the substrate support assembly 104. After positioning of the substrate 105, process gases are supplied from a gas panel 132 through entry ports 134 into the internal volume 124 of the chamber body 101. The process gases are ignited into a plasma 116 in the processing chamber 100 by applying power from the RF power supply 121 to the first and second coils 118, 120. The pressure within the internal volume 124 of the processing chamber 100 may be controlled using a valve 136 and a vacuum pump 138. Voltages applied to the substrate electrode 109 and the edge electrode 156 may be independently adjusted to improve the process uniformity.

The processing chamber 100 includes the controller 108 to control the operation of the processing chamber 100 during processing. The controller 108 comprises a central processing unit (CPU) 140, a memory 142, and support circuits 144 for the CPU 140 and facilitates control of the components of the processing chamber 100. The controller 108 may be any form of a general-purpose computer processor that can be used in an industrial setting for controlling various chambers and sub-processors. The memory 142 stores software (source or object code) that may be executed or invoked to control the operation of the processing chamber 100 in the manner described herein.

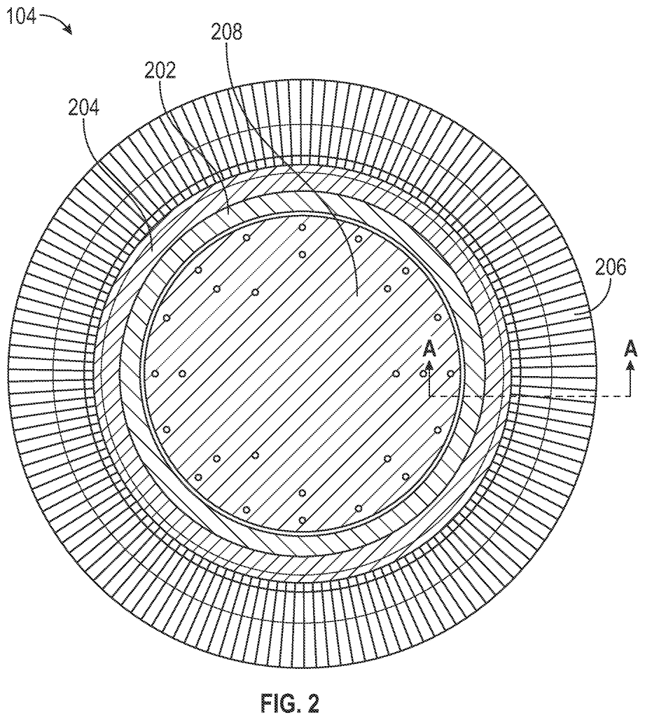

FIG. 2 illustrates a schematic top view of the substrate support assembly 104, according to an embodiment. The substrate support assembly 104 includes a susceptor 208 configured to support a substrate. The susceptor 208 is surrounded by a protective ring 202 configured to protect the edge electrode 156 of the edge voltage delivery system 106. The protective ring 202 is surrounded by an edge ring 204 configured to protect the edge electrode 156 along a peripheral direction of the edge electrode 156. The protective ring 202 may be made of a dielectric material, such as silicon carbide, quartz, ceramic, aluminum oxide, silicon nitride, or other suitable dielectric material. The protective ring 202 may include a protective coating, such as yttrium oxide (Y₂O₃), alumina, polysilicon, or other protective coating. The protective ring 202 may also include a protective coating, such as polysilicon, silicon nitride, or other suitable material. The edge ring 204 may be made of similar materials or coatings as the protective ring 202. Detailed configurations of the protective ring 202 and the edge ring 204 will be provided later in the present disclosure. Also shown in FIG. 2, the substrate support assembly 104 includes a plasma screen 206 disposed around the substrate support assembly 104.

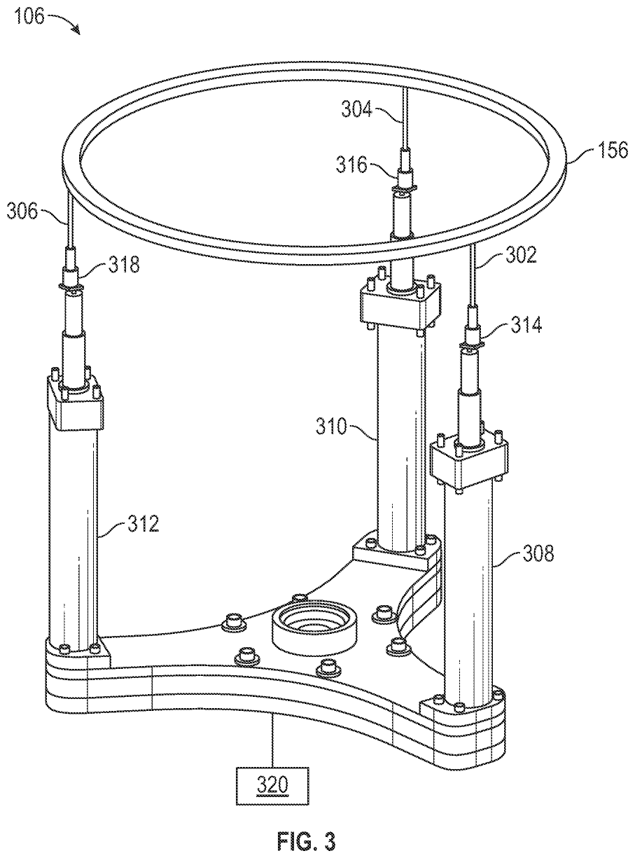

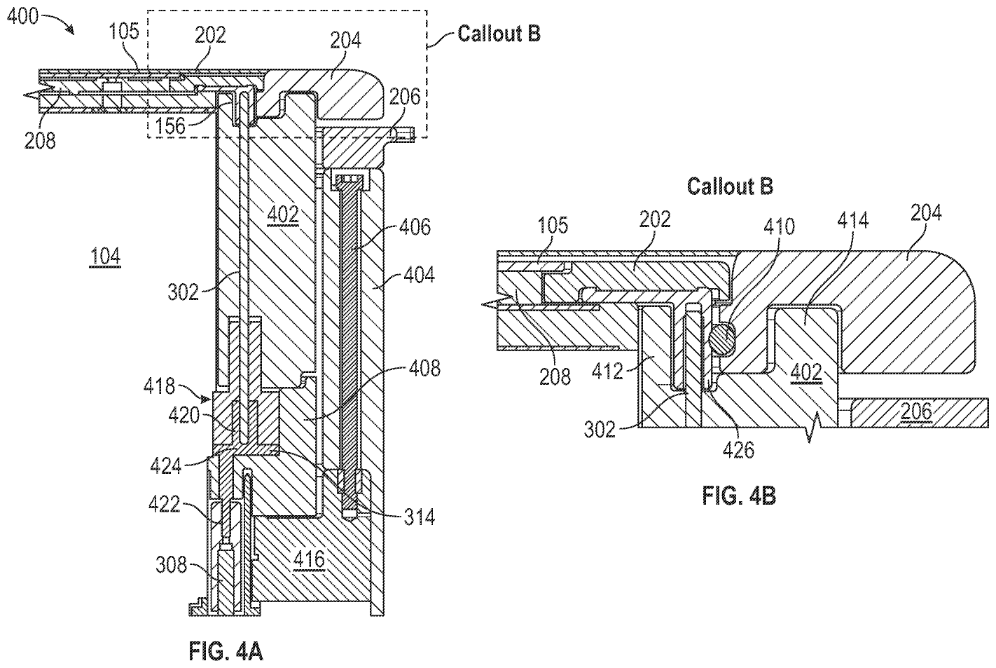

FIG. 3 illustrates a schematic configuration of edge voltage delivery system 106, according to an embodiment. The edge voltage delivery system 106 includes a plurality of lower feed lines 308, 310, 312, a plurality of upper feed lines 302, 304, 306, and an annular edge electrode 156. The edge voltage delivery system 106 may further includes a protective ring 202 and an edge ring 204 (shown in FIGS. 2 and 4).

The lower and upper feed lines are configured to transmit electrical signal from an external source 320 to the edge electrode 156. The plurality of the lower feed lines 308, 310, 312 are disposed substantially outside the substrate support assembly 101, while the plurality of the upper feed lines 302, 304, 306 are disposed within the substrate support assembly 104. The lower feed line 308 is coupled with the upper feed line 302 via an optional connector plug 314. The lower feed line 310 is coupled with the upper feed line 304 via another optional connector plug 316. The lower feed line 312 is coupled with the upper feed line 306 via yet another optional connector plug 318. The connector plugs 314, 316, 318 are configured to bridge any offset of positions between the upper feed lines and lower feed lines.

In an embodiment, the upper feed lines 302, 304, 306 are coupled to a lower surface of the edge electrode 156. The upper feed lines 302, 304, 306 may be disposed at equal distance along the perimeter of the edge electrode 156. As shown in FIG. 3, three (3) upper feed lines are coupled to the edge electrode 156 and may be arranged at a 120 degree angle separated from each other. It is contemplated that the edge electrode 156 may include more than three (3) feed lines, such as four (4), five (5), six (6), twelve, or even more feed lines.

The edge electrode 156 is configured to be disposed in proximity to a substrate. In an embodiment, the edge electrode is substantially annular. The edge electrode may be made of a conductive material, such as aluminum, copper, or other suitable conductive materials. A protective coating may be additionally deposited on the edge electrode to resist the plasma chemistry during the substrate processing. The protective coating may be similar as the coating of the protective ring 202, such as yttrium oxide (Y₂O₃), alumina, polysilicon, or other protective coating.

FIG. 4A illustrates a schematic cross-sectional view 400 of the substrate support assembly 104 along line A-A in FIG. 2, according to an embodiment. FIG. 4B illustrates details in Callout B of FIG. 4A, according to an embodiment. As shown in FIG. 4A, the lower feed line 308 enters the substrate support assembly 104 via a conduit formed in a ground plate 416. The lower feed line 308 is coupled with a connector plug 314, which is coupled with the upper feed line 302. In an embodiment, the connector plug 314 is disposed substantially within a facility plate 408. The connector plug 314 includes two terminals 420 and 422 disposed at opposite sides of a plate 424. The two terminals 420, 422 are offset horizontally. The terminal 422 is coupled with the lower feed line 308, while the terminal 420 is coupled with the upper feed line 302. An insulator sleeve 418 isolates the plate 424 and the terminal 420 from other parts of the substrate support assembly. The upper feed line 302 is disposed within a quartz liner 402, which extends underneath the edge electrode 156 and an edge ring 204 at an upper end of the quartz liner. The insulator sleeve 418 extends from the plate 424 into the quartz liner 402.

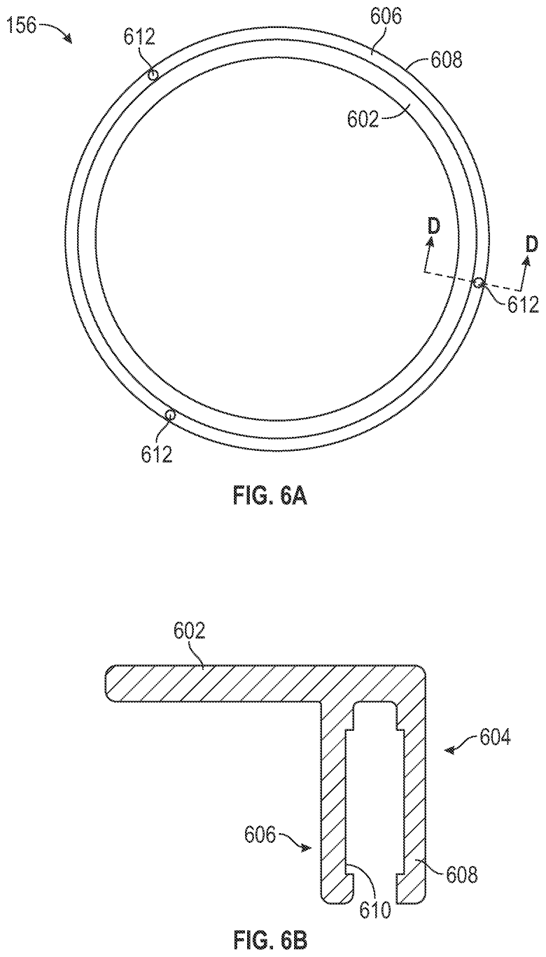

In an embodiment, the quartz liner 402 includes two protrusions 412 and 414 at the upper end 428, which form a pocket 426 (shown in FIG. 4B) configured to couple with the edge electrode 156 and the edge ring 204. The upper feed line 302 extends into the pocket 426 and couple with the edge electrode 156 within the pocket 426. As shown in FIG. 4B, a seal 410, such as an O-ring, is disposed within the pocket 426 to seal any gaps between the edge electrode 156 and the edge ring 204. The edge electrode 156 has an L-shape. One leg (604 shown in FIG. 6B) of the L-shape is disposed within the pocket 426, while the other leg (602 shown in FIG. 6B) is disposed horizontally and outside the pocket 426. The edge electrode 156 is covered by the protective ring 202. In an embodiment, the horizontal leg (602 shown in FIG. 6B) of the edge electrode 156 is disposed in a groove of the protective ring. Details of the edge electrode 156, the protective ring 202, and the edge ring 204 will be provided later in the present disclosure.

As shown in FIG. 4A, the plasma screen 206 is disposed below the edge ring 204. The plasma screen 206 is coupled with a conductive rod 406 that is disposed within another quartz liner 404. The conductive rod 406 is coupled to the ground plate 416.

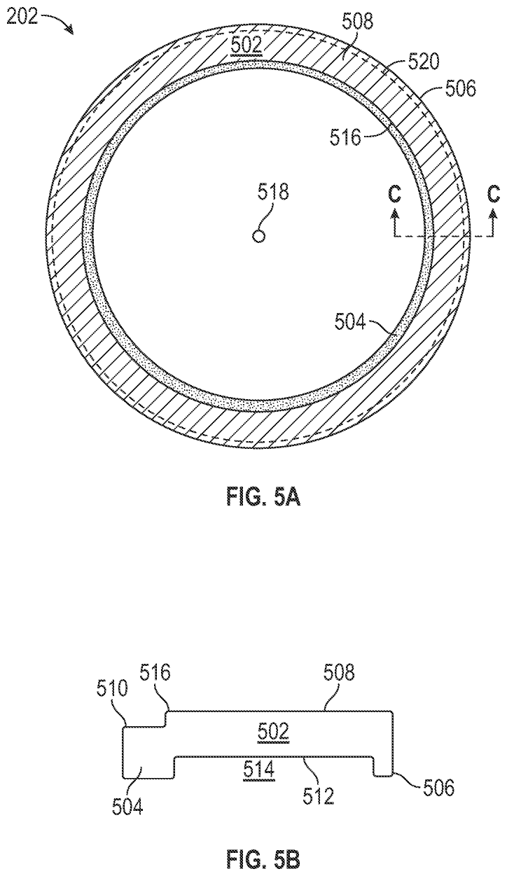

FIG. 5A illustrates schematic top view of the protective ring 202, according to an embodiment. FIG. 5B illustrate a schematic cross-sectional view along lines C-C in FIG. 5A. The protective ring 202 includes an annular body 502 having a top surface 508 and a bottom surface 512. The protective ring 202 also includes a protrusion 504 disposed along an inner perimeter 516 of the annular body 502. The protrusion 504 includes a top surface 510 disposed below the top surface 508. The top surface 510 is disposed below a top surface of the susceptor 208. The protrusion 504 is configured to maintain a clearance gap between the edge electrode 156 and the edges of the susceptor 208.

The protective ring 202 may further include a skirt 506 disposed along an outer perimeter of the protective ring 202. The skirt 506 extends downwardly from the bottom surface 512 of the body 502. The skirt 506, the bottom surface 512, and the protrusion 504 form a groove 514 configured to receive the edge electrode 156. The groove forms a circle 520 within the annular body.

In an embodiment, the protective ring 202 may be made of a dielectric material that is resistant to the processing chemistry in the processing chamber 100. Suitable dielectric material may include quartz, silicon carbide, silicon nitride, or polysilicon, among others. The top surface 508 may include one or more coatings to improve resistance to the chemistry. In an embodiment, the top surface 508 may be inclined inwardly toward a center 518 of the edge ring with an angle ranging from 1 degree to 10 degrees, such as about 5 degrees.

FIG. 6A illustrates schematic bottom view of the edge electrode 156, according to an embodiment. FIG. 6B illustrate a schematic cross-sectional view along lines D-D in FIG. 6A. The edge electrode 156 has a general L shape with a horizontal leg 602 coupled with two vertical legs 608 and 606. A channel 610 is formed by the two vertical legs 608 and 606 and is configured to receive the upper feed lines. A plurality of coupling locations 612 are disposed along the channel 610 for coupling with the feed lines. The length of the horizontal leg 602 is sized to be fit into the groove 514 of the protective ring 202. The edge electrode 156 is substantially annular and surrounds the susceptor 208.

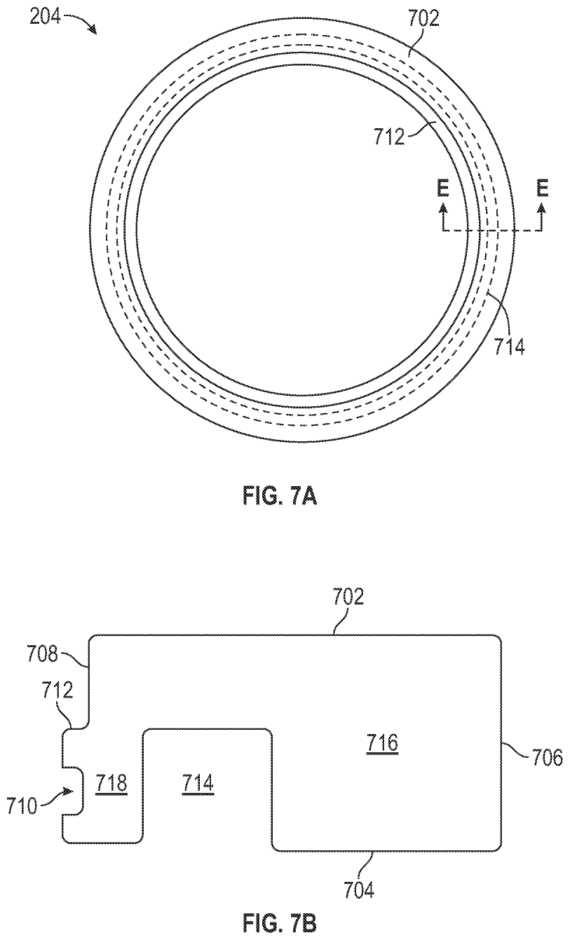

FIG. 7A illustrates a schematic bottom view of the edge ring 204, according to an embodiment. FIG. 7B illustrate a schematic cross-sectional view along lines E-E in Figure A. The edge ring 204 is also substantially annular and surrounds both the protective ring 202 and the edge electrode 156 (shown in FIG. 4A). The edge ring 204 may be made of similar materials as the protective ring, such as quartz, silicon nitride, alumina, polysilicon, and other suitable dielectric material. The edge ring 204 has a generally rectangular cross-section with a groove 714 disposed at the bottom surface 704. The groove 714 is sized to receive the protrusion 414 of the quartz liner 402. The edge ring 204 also includes a top surface 702, an inner perimeter 708 and an outer perimeter 706. The top surface 702 is configured to be higher than that of the protective ring 202. The inner perimeter 706 abuts the protective ring 202. A seal groove 710 is disposed along the inner perimeter 708 to receive the seal 410 and abuts the edge electrode 156 (shown in FIG. 4B). A top wall 712 of the groove 710 is configure to couple with the skirt 506 of the protective ring 202.

Benefits of the disclosure include the ability to adjust plasma sheaths at the substrate edge in lieu of replacing chamber components, thereby improving device yield while mitigating downtime and reducing expenditures on consumables. Additionally, aspects described herein allow for the plasma sheath to be adjusted at the substrate edge without affecting the plasma parameters at substrate center, thereby providing a tuning knob for extreme edge process profile control and feature tilting correction.

What is claimed is:

1. A protective ring for a substrate support assembly, the protective ring comprising:
an annular body comprising a first top surface and a first bottom surface;
a protrusion disposed along an inner perimeter of the annular body and comprising a second top surface and a second bottom surface, the second top surface being disposed below the first top surface; and
a skirt disposed along an outer perimeter of the annular body and extending downwardly from the first bottom surface,
wherein the skirt, the protrusion, and the first bottom surface form a groove under the annular body.

2. The protective ring of claim 1, wherein the annular body comprises a dielectric material selected from the group consisting of quartz, alumina, silicon carbide, silicon nitride, and polysilicon.

3. The protective ring of claim 2, wherein the first top surface comprises a coating made of a material selected from the group consisting of silicon carbide, silicon nitride, and polysilicon.

4. The protective ring of claim 2, wherein the first top surface inclines inwardly toward a center of the protective ring at an angle between about 1 degree to about 10 degrees.

5. The protective ring of claim 1, wherein the groove forms a circle within the annular body.

6. The protective ring of claim 1, wherein the protrusion extends downwardly from the first bottom surface.

7. An edge voltage delivery system for a substrate support assembly, the edge voltage delivery system comprising:
a protective ring comprising an annular body, a protrusion disposed along an inner perimeter, a skirt disposed along an outer perimeter of the annular body, and a groove, wherein the annular body comprises a first top surface and a first bottom surface, the protrusion comprises a second top surface and a second bottom surface, the second top surface is disposed below the first top surface, the skirt extends downwardly from the first bottom surface, and the skirt, the protrusion, and the first bottom surface form the groove under the annular body;
an edge electrode made of a conductive material and disposed under the protective ring, the edge electrode contacting the protective ring; and
a plurality of electrical feed lines coupled with the edge electrode.

8. The edge voltage delivery system of claim 7, wherein the annular body comprises a dielectric material selected from the group consisting of quartz, alumina, silicon carbide, silicon nitride, and polysilicon.

9. The edge voltage delivery system of claim 8, wherein the protrusion extends downwardly from the first bottom surface.

10. The edge voltage delivery system of claim 7, further wherein the plurality of the electrical feed lines comprise an upper electrical feed line coupled with a lower electrical feed line that is offset horizontally from the upper electrical feed line.

11. The edge voltage delivery system of claim 10, further comprising a quartz liner, wherein the plurality of the upper electrical feed lines are disposed within the quartz liner.

12. The edge voltage delivery system of claim 11, further comprising a connector plug coupling the upper electrical feed line and the lower electrical feed line, wherein the connector plug extends into the quartz liner.

13. The edge voltage delivery system of claim 7, wherein the edge electrode comprises a horizontal plate coupled with a vertical leg, and wherein the horizontal plate is disposed within the groove.

14. The edge voltage delivery system of claim 13, wherein the plurality of the electrical feed lines are coupled with the vertical leg.

15. A substrate support assembly for a processing chamber comprising:
a susceptor configured to support a substrate;
an edge ring surrounding the susceptor; and
an edge voltage delivery system configured to deliver an electrical signal in proximity to an edge of the susceptor,
wherein the edge voltage delivery system comprises:
a protective ring comprising an annular body, a protrusion disposed along an inner perimeter, a skirt disposed along an outer perimeter of the annular body, and a groove, wherein the annular body comprises a first top surface and a first bottom surface, the protrusion comprises a second top surface and a second bottom surface, the second top surface is disposed below the first top surface, the skirt extends downwardly from the first bottom surface, and the skirt, the protrusion, and the first bottom surface form the groove under the annular body;
an edge electrode made of a conductive material and disposed under the protective ring, the edge electrode contacting the protective ring; and
a plurality of electrical feed lines coupled with the edge electrode.

16. The substrate support assembly of claim 15, wherein the annular body comprises a dielectric material selected from the group consisting of quartz, alumina, silicon carbide, silicon nitride, and polysilicon.

17. The substrate support assembly of claim 16, wherein the protrusion extends downwardly from the first bottom surface.

18. The substrate support assembly of claim 15, wherein the edge electrode comprises a horizontal plate coupled with a vertical leg, wherein the horizontal plate is disposed within the groove.

19. The substrate support assembly of claim 15, wherein the edge ring comprises a seal groove disposed along an inner perimeter of the edge ring and configured to receive a seal disposed between the edge electrode and the edge ring.

20. The substrate support assembly of claim 19, wherein the skirt is supported by an upper wall of the seal groove of the edge ring.
